(19) United States
(12) Patent Application Publication
(10) Pub. No.: US 2023/0356113 A1
(43) Pub. Date: Nov. 9, 2023

(54) VAPOR CHAMBER WITH IMPROVED FIXING STRUCTURE FOR DEGASSING TUBE

(71) Applicant: TAIWAN MICROLOOPS CORP., New Taipei City (TW)

(72) Inventor: Chun-Hung LIN, New Taipei City (TW)

(21) Appl. No.: 17/891,123

(22) Filed: Aug. 18, 2022

(30) Foreign Application Priority Data
May 6, 2022 (TW) 111117159

(51) Int. Cl. B01D 19/00; F28D 15/02; F28F 11/00

(52) U.S. Cl. CPC B01D 19/0036; F28D 15/0283; F28F 11/00; H05K 7/2039

(57) ABSTRACT

A vapor chamber includes a vapor chamber main body, a degassing tube, and a fixing layer. The vapor chamber main body includes a first casing and a second casing correspondingly sealed with the first casing. The first casing is disposed with a tube trough. One of the first casing and the second casing is formed with a filling hole corresponding to the tube trough. The degassing tube is placed in the tube trough. A feeding channel communicating with the filling hole is formed between the degassing tube, the tube trough and the second casing. The fixing layer is formed in the feeding channel to fasten the degassing tube on the vapor chamber main body. Therefore, the production procedure may be simplified and the degassing tube may be firmly fastened on the vapor chamber main body.

### BACKGROUND

### Technical Field

The disclosure relates to a vapor chamber, particularly to a vapor chamber with an improved fixing structure for a degassing tube.

### Description of Related Art

To solve the cooling problem of electronic components, the industry has developed cooling elements with high performance, such as heat pipes and vapor chambers. A vapor chamber has a wide covering range and a short thermoconductive path, so its cooling performance is better than a heat pipe. Thus, vapor chambers have gradually become a primary cooling element for electronic components.

However, the manufacturing of the degassing tube of a vapor chamber is to closely seal an upper casing and a lower casing first, then punch or slot the casings by the second processing, and finally insert the degassing tube into the hole or slot and weld the casings. This manufacturing process requires high frequency machining and annealing, so it is quite cumbersome and complicated. Obviously, it cannot satisfy the using requirements.

In view of this, the inventors have devoted themselves to the above-mentioned related art, researched intensively and cooperated with the application of science to try to solve the above-mentioned problems. Finally, the invention which is reasonable and effective to overcome the above drawbacks is provided.

### SUMMARY

An object of the disclosure is to provide a vapor chamber with an improved fixing structure for a degassing tube, which may simplify the manufacturing process, and stably fasten the degassing tube on the vapor chamber main body.

To accomplish the above object, the disclosure provides a vapor chamber with an improved fixing structure for a degassing tube, which includes a vapor chamber main body, a degassing tube, and a fixing layer. The vapor chamber main body includes a first casing and a second casing correspondingly sealed with the first casing. The first casing is disposed with a tube trough. One of the first casing and the second casing is formed with a filling hole corresponding to the tube trough. The degassing tube is placed in the tube trough. A feeding channel communicating with the filling hole is formed between the degassing tube, the tube trough and the second casing. The fixing layer is formed in the feeding channel to fasten the degassing tube on the vapor chamber main body.

The disclosure further has the following functions. When assembling the first casing and the second casing, the degassing tube may be fixed at the same time to eliminate the processes of high frequency machining and annealing. When various problems such as degassing occur during the manufacturing process, it is easy to deweld the degassing tube from the vapor chamber main body.

### BRIEF DESCRIPTION OF THE DRAWINGS

FIG. 1 is an exploded view of the vapor chamber of the disclosure;

FIG. 2 is a partially enlarged view of FIG. 1;

FIG. 3 is a schematic view of the degassing tube placed on the vapor chamber main body of the disclosure;

FIG. 4 is a cross-sectional view of the degassing tube placed on the vapor chamber main body of the disclosure;

FIG. 5 is a cross-sectional view of the pasty fixing layer entering the feeding channel from the filling hole of the disclosure;

FIG. 6 is a cross-sectional view of the fixing layer filled in the feeding channel and the filling hole of the disclosure;

FIG. 7 is a perspective view of the fixing layer filled in the feeding channel and the filling hole of the disclosure;

FIG. 8 is a schematic view of the degassing tube withdrawn from the vapor chamber main body after dewelding of the disclosure;

FIG. 9 is an explode view of another embodiment of the vapor chamber of the disclosure; and

FIG. 10 is an assembled schematic view of still another embodiment of the vapor chamber of the disclosure.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

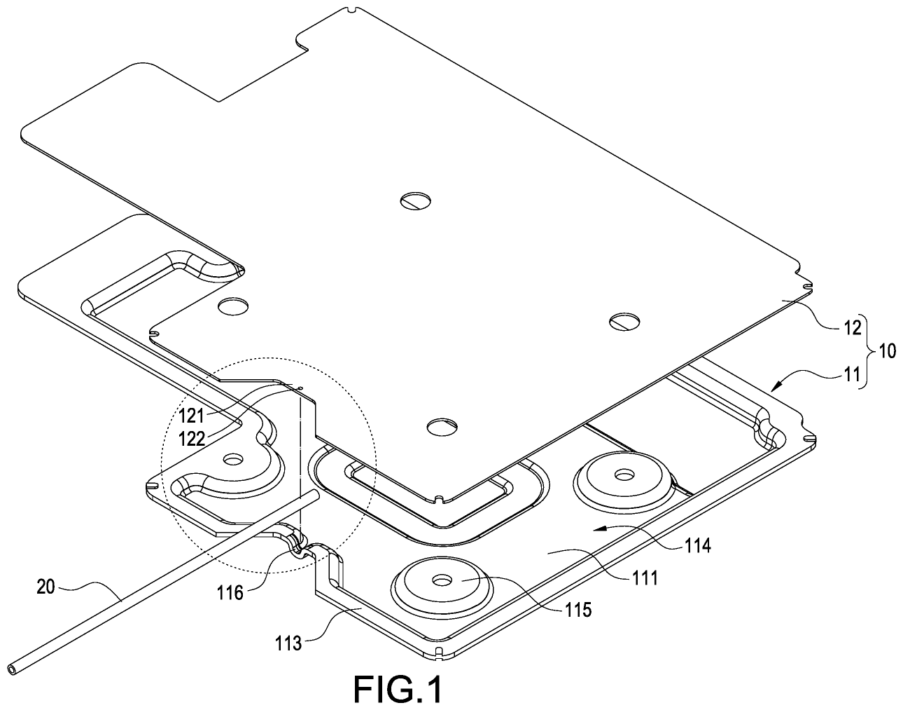

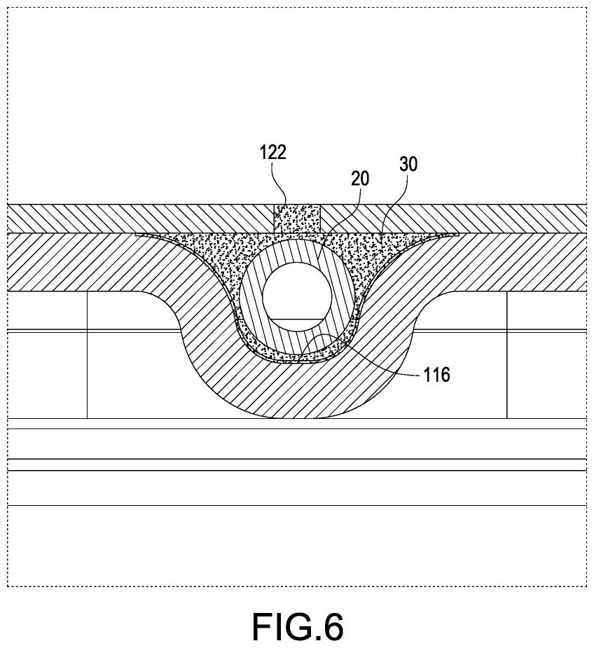

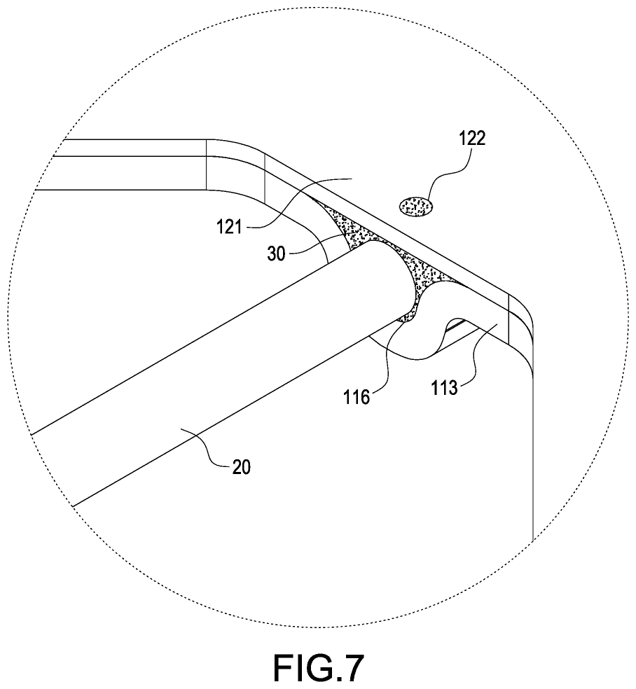

Please refer to FIGS. 1-7. The disclosure provides a vapor chamber with an improved fixing structure for a degassing tube, which includes a vapor chamber main body 10, a degassing tube 20 and a fixing layer 30.

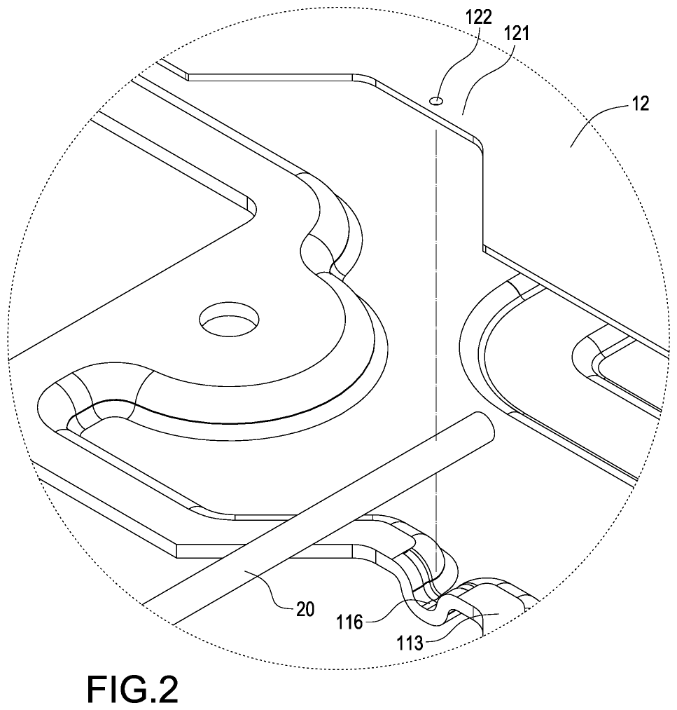

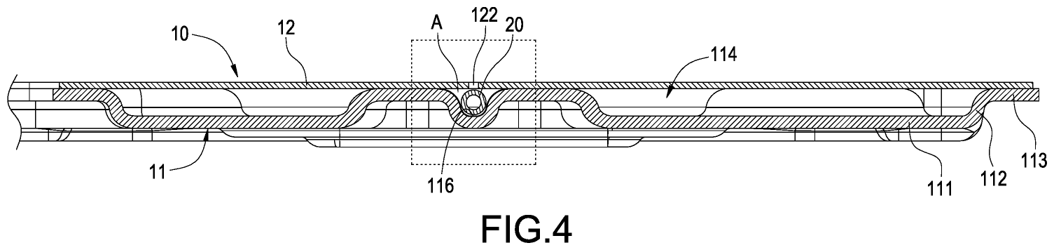

Please refer to FIGS. 1 and 2. The vapor chamber main body 10 includes a first casing 11 and a second casing 12. The first casing 11 is made of a material with desirable thermo-conductivity such as copper, aluminum, magnesium, or an alloy thereof. The first casing 11 is of a substantially polygonal shape and includes a bottom plate 111, a surrounding plate 112 upward extended from a periphery of the bottom plate 111 as shown in FIG. 4, and a flange 113 bent and extended from a periphery of the surrounding plate 112. A cavity 114 is enclosed jointly between the bottom plate 111 and the surrounding plate 12. The bottom plate 111 is upward extended with multiple support bumps 115 in the cavity 114. Also, the surrounding plate 112 and the flange 113 are disposed with a tube trough 116.

The second casing 12 is made of a material with desirable thermo-conductivity such as copper, aluminum, magnesium, or an alloy thereof. In an embodiment, the second casing 12 is, but not limited to, a flat plate and is correspondingly sealed with the first casing 11. An inner edge 121 is formed in the contour of the second casing 12. A position on the inner edge 121 of the second casing 12 corresponding to the tube trough 116 is disposed with a filling hole 122. In the embodiment, the filling hole 122 is a round through hole.

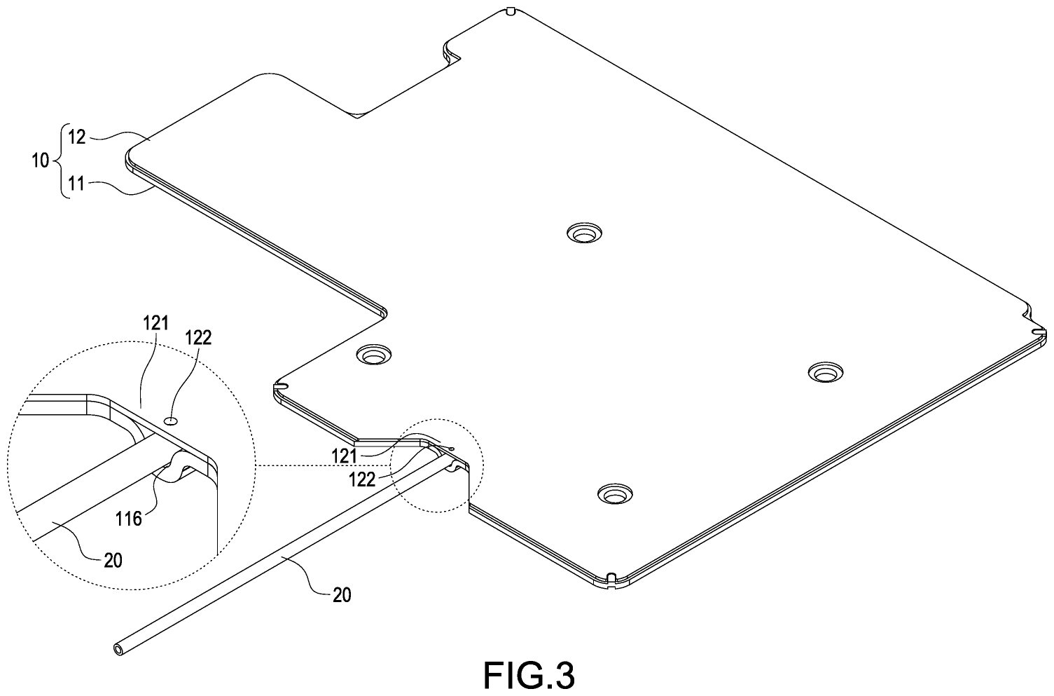

Please refer to FIGS. 3 and 4. The degassing tube 20 is placed in the tube trough 116. A feeding channel A is defined between an outer surface of the degassing tube 20, an inner surface of the tube trough 116 and the second casing 12. The feeding channel A communicates with the filling hole 122.

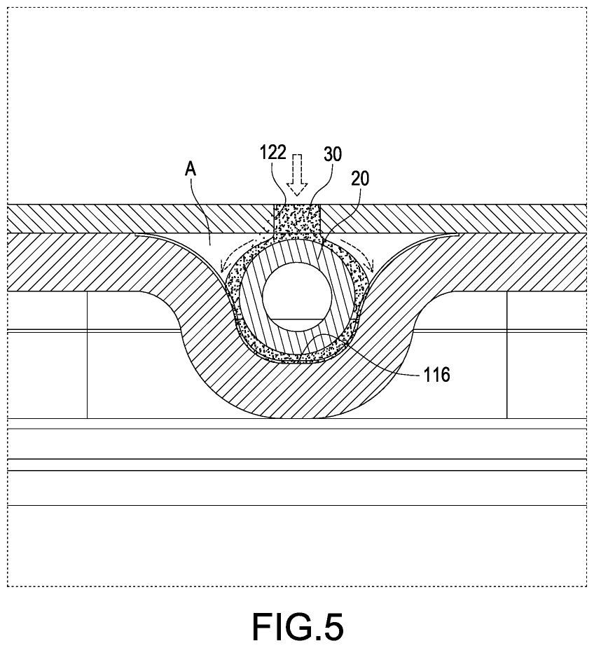

Please refer to FIGS. 5-7. The fixing layer 30 is a copper paste made of a copper powder base material mixed with an adhesive, and is filled through the filling hole 122 and enters along the feeding channel A. The fixing layer 30 fastens the degassing tube 20 on the vapor chamber main body 10 by a solidification process.

When assembling, a welding base material (not shown in figures) is coated on the flange 113 of the first casing 11 and the inner edge 121 of the second casing 12, an end of the degassing tube 20 is placed corresponding to the tube trough 116, and the copper paste is placed on the filling hole 122 and treated with heating and pressing for connection. As a result, the first casing 11 is correspondingly sealed with the second casing 12. The copper paste enters through the filling hole 122, flows in along the feeding channel A, and forms the fixing layer 30 by a solidification process.

Next, a working fluid such as pure water is filled in the cavity 114 from the degassing tube 20. Finally, the above assembled structure is heated to eject air in the cavity 114. The degassing tube 20 is treated with sealing to make the cavity 114 form a vacuum chamber so as to finish the manufacturing of a vapor chamber.

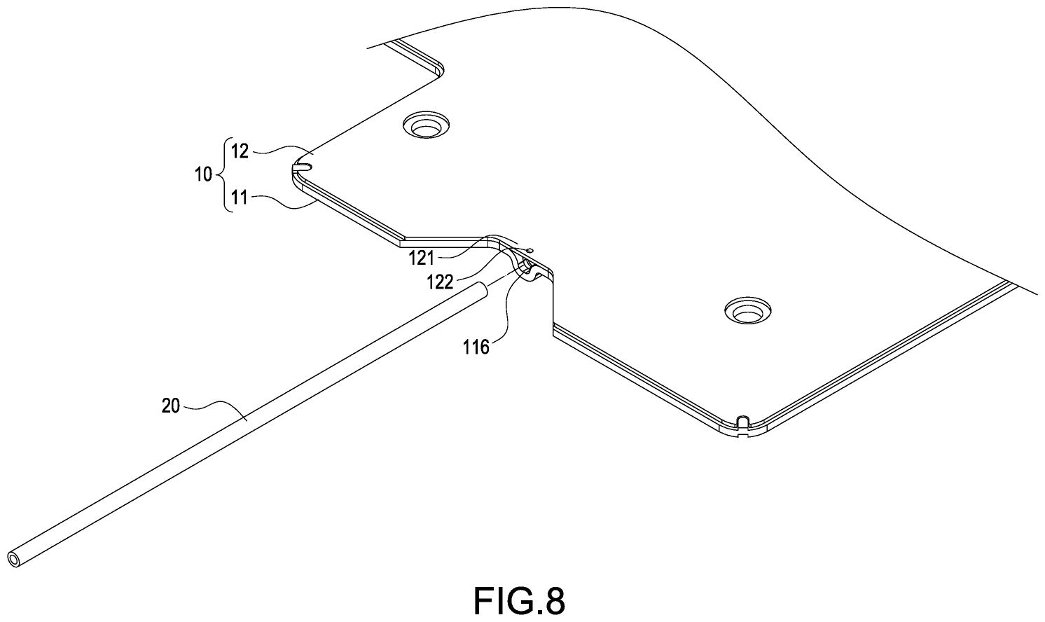

Please refer to FIG. 8. After the above assembling process, if various problems occur in the degassing tube 20 such that degassing cannot be implemented completely or normally, the fixing layer 30 may be melted by partially heating the vapor chamber main body 10 to easily deweld the degassing tube 20 from the vapor chamber main body 10.

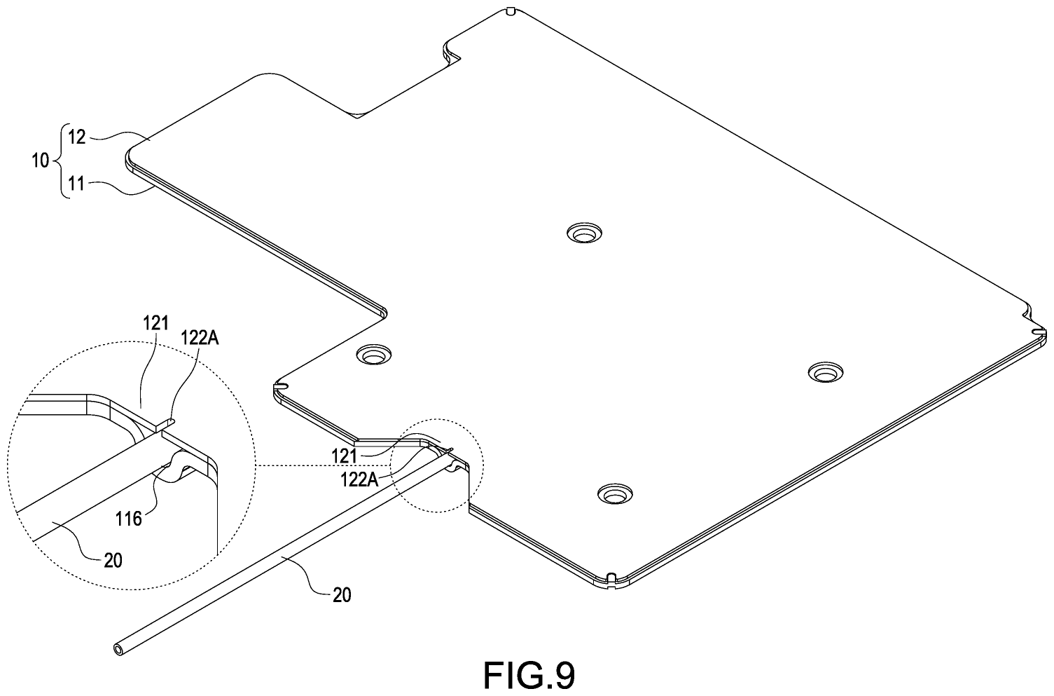

Please refer to FIG. 9. In an embodiment for the filling hole 122, besides being embodied as the above through hole, the filling hole 122A may be embodied as a notch disposed on the inner edge 121 of the second casing 12 as the embodiment.

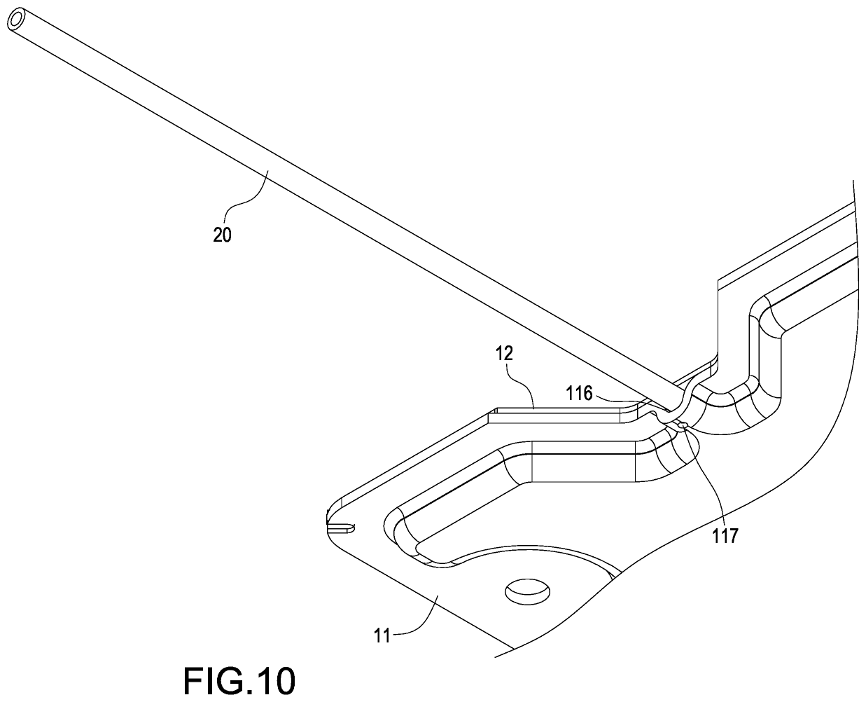

Please refer to FIG. 10. In an embodiment for the filling hole, besides being the filling hole 122 disposed on the inner edge 121 of the second casing 12, it may also be the filling hole 117 of the embodiment, which is disposed on the flange 113 of the first casing 11 and arranged corresponding to the tube trough 116. The filling hole 117 may also be a through hole or a notch.

While this disclosure has been described by means of specific embodiments, numerous modifications and variations could be made thereto by those skilled in the art without departing from the scope and spirit of this disclosure set forth in the claims.

What is claimed is:

1. A vapor chamber comprising:
a vapor chamber main body, comprising a first casing and a second casing correspondingly sealed with the first casing, the first casing comprising a tube trough, wherein a filling hole is disposed on one of the first casing and the second casing corresponding to the tube trough;
a degassing tube, placed in the tube trough, wherein a feeding channel is defined between the degassing tube, the tube trough and the second casing, and the feeding channel communicates with the filling hole; and
a fixing layer, disposed in the feeding channel to fasten the degassing tube on the vapor chamber main body.

2. The vapor chamber of claim 1, wherein the filling hole is a through hole defined on the second casing.

3. The vapor chamber of claim 1, wherein the filling hole is a notch defined on the second casing.

4. The vapor chamber of claim 1, wherein the fixing layer comprises a curable copper paste.

5. The vapor chamber of claim 1, wherein the filling hole is a through hole or a notch defined on the first casing.

6. The vapor chamber of claim 1, wherein the first casing comprises a bottom plate, a surrounding plate upward extended from the bottom plate, and a flange bent and extended from the surrounding plate, and the tube trough is disposed on the surrounding plate and the flange.

7. The vapor chamber of claim 6, wherein a cavity is enclosed jointly between the bottom plate and the surrounding plate, and the bottom plate is upward extended with multiple support bumps in the cavity.

8. The vapor chamber of claim 1, wherein the second casing comprises an inner edge, and the filling hole is disposed on the inner edge.
